(19) United States
(12) Patent Application Publication
(10) Pub. No.: US 2018/0277766 A1
(43) Pub. Date: Sep. 27, 2018

(54) THERMALLY ACTIVATED DELAYED FLUORESCENCE ORGANIC LIGHT EMITTING DIODE HAVING HOST MATRIX POLARITY CO-DOPING

(71) Applicants: THE REGENTS OF THE UNIVERSITY OF CALIFORNIA, Oakland, CA (US); Dow Global Technologies LLC, Midland, MI (US)

(72) Inventors: Sukrit Mukhopadhyay, Midland, MI (US); Timothy S. De Vries, Midland, MI (US); David D. Devore, Midland, MI (US); Dannielle McCarthy, Alameda, CA (US); Benjamin Cotts, Vestal, NY (US); Rodrigo Javier Noriega-Manez, Salt Lake City, UT (US); Naomi Shauna Ginsberg, Oakland, CA (US)

(21) Appl. No.: 15/469,746

(22) Filed: Mar. 27, 2017

(51) Int. Cl. H01L 51/00; C09K 11/06

(52) U.S. Cl. CPC H01L 51/0071; C09K 11/06; H01L 51/007; H01L 51/5028; H01L 51/004; H01L 51/0072; H01L 51/0073

(57) ABSTRACT

Disclosed herein is a composition comprising a host material; a fluorescent emitter, wherein the host material and the emitter are different from each other; and a codopant comprising a small molecule that has a polarity that is different from that of the host material; where the codopant modulates an energy gap of the fluorescent emitter to enhance thermally activated delayed fluorescence of the fluorescent emitter in a solid state. Disclosed herein too is a method comprising blending together a solvent, a host material, a fluorescent emitter, and a codopant, wherein the host material and the emitter are different from each other; and wherein the codopant comprising a small molecule that has a polarity that is different from that of the host material; where the codopant modulates an energy gap of the fluorescent emitter to enhance thermally activated delayed fluorescence of the fluorescent emitter in a solid state.

### BACKGROUND

This disclosure relates to an organic light emitting diode. In particular, this disclosure relates to a thermally activated delayed fluorescence organic light emitting diode having host matrix polarity co-doping.

Organic light emitting diodes (OLEDs) are electroluminescent devices that convert charge into light. OLEDs are more energy efficient and have better display performance metrics (contrast, etc.) than previous display technologies. Currently OLEDs have already been adopted into RGB (red/blue/green) displays in commercial applications such as phones, TVs, and the like. However, the limiting capabilities of OLEDs in blue pixels prevent the widespread use of OLEDs in commercial displays. In particular, the higher operating energy of blue pixels leads to increased probability of degradation byproducts.

In addition, when two random charges (hole and electron) reach an emitter molecule they both have random spin. When these two charges or two random spins recombine in an emitter molecule they form triplets and singlet excitations in a 3:1 ratio. This sets limits on OLED efficiency due to the emissive properties of organic molecules. Without any intersystem crossing, a fluorescent OLED is limited to a maximum internal quantum efficiency (IQE→photons out/charge pairs in) of 25%, and all triplet excitations are lost to non-radiative pathways. As such, it is advantageous to design OLEDs to use emitter molecules that include some mechanism in order to interconvert between triplets and singlets to be able to reach 100% IQE.

Current commercial OLEDs feature an inorganic emitter, which consists of a heavy metal center surrounded by organic ligands. This heavy metal center serves to increase the spin orbit coupling of the molecule, which increases the efficiency of intersystem crossing, allowing all singlet excitations to cross over into the triplet state. Then, as coupling between the normally dark triplet state and the singlet ground state is also increased, all excitations can be captured through phosphorescent emission. In a RGB display, this works well for red and green OLEDs, but has yet to show long term stability for blue pixels. This has caused manufacturers to use inorganic phosphorescence OLEDs (PHOLEDs) for the green and red pixels and fluorescent emitters for the blue (limited to 25% IQE). This necessitates the use of a larger blue pixel, which operates less efficiently and also uses more material to manufacture.

It is therefore desirable to develop light emitting OLEDs that are stable and efficient and that are capable of being used in commercial products.

### SUMMARY

Disclosed herein is a composition comprising a host material; a fluorescent emitter, wherein the host material and the emitter are different from each other; and a codopant comprising a small molecule that has a polarity that is different from that of the host material; where the codopant modulates an energy gap of the fluorescent emitter to enhance thermally activated delayed fluorescence of the fluorescent emitter in a solid state.

Disclosed herein too is a method comprising blending together a solvent, a host material, a fluorescent emitter, and a codopant, wherein the host material and the emitter are different from each other; and wherein the codopant comprising a small molecule that has a polarity that is different from that of the host material; where the codopant modulates an energy gap of the fluorescent emitter to enhance thermally activated delayed fluorescence of the fluorescent emitter in a solid state.

### BRIEF DESCRIPTION OF THE FIGURES

These and/or other aspects will become apparent and more readily appreciated from the following description of the exemplary embodiments, taken in conjunction with the accompanying drawings in which:

FIG. 1A is an illustration showing a ternary mixture according to an embodiment;

FIG. 1B is a schematic showing an organic light emitting diode device according to an embodiment;

FIG. 2A is a schematic comparison of an emitter in a nonpolar and in a polar medium according to an embodiment;

FIG. 2B is a graph of normalized intensity (au) versus wavelength (nm) showing the solvent dependency of an emitter according to an embodiment;

FIG. 3A is a graph of normalized intensity (au) versus wavelength (nm) showing the concentration dependency of a codopant according to an embodiment;

FIG. 3B is a graph of maximum emission photoluminescence peak (nm) versus weight percent of codopant according to an embodiment;

FIG. 4 is a graph of photoluminescence intensity (au) versus wavelength (nm) showing the effect of codopant concentration at different excitation wavelengths according to an embodiment;

FIG. 5A is a graph of photoluminescence quantum yield versus weight percent of codopant according to an embodiment;

FIG. 5B is a schematic comparison of an emitter in a nonpolar and in a polar medium according to an embodiment along with a sketch of the behavior of the photoluminescence and electroluminescence quantum yields as a function of weight percent of codopant according to an embodiment;

FIG. 6A is a graph of normalized intensity (au) versus time (ns) showing the changes in photoluminescence prompt lifetime based on codopant concentration according to an embodiment;

FIG. 6B is a graph of average prompt lifetime (ns) versus weight percent of codopant according to an embodiment;

FIG. 7A is a graph of normalized intensity (au) versus time (μs) showing the changes in photoluminescence delayed lifetime based on codopant concentration according to an embodiment;

FIG. 7B is a graph of average delayed lifetime (μs) versus weight percent of codopant according to an embodiment;

FIG. 8A is a graph of normalized intensity (au) versus wavelength (nm) showing the concentration dependency of a codopant according to an embodiment;

FIG. 8B is a graph of normalized intensity (au) versus time (ns) showing the changes in photoluminescence prompt lifetime based on codopant concentration according to an embodiment;

FIG. 9A is a graph of normalized intensity (au) versus wavelength (nm) showing the concentration dependency of a codopant according to an embodiment; and

FIG. 9B is a graph of normalized intensity (au) versus time (ns) showing the changes in photoluminescence prompt lifetime based on codopant concentration according to an embodiment.

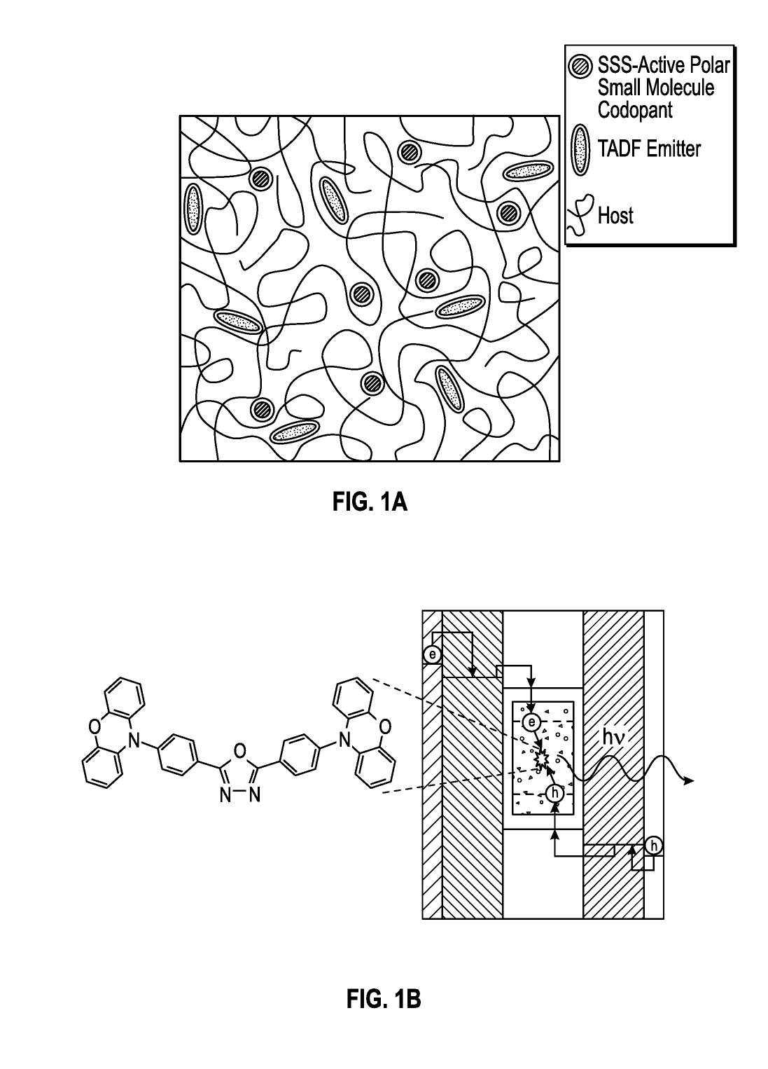

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The terminology used herein is for the purpose of describing particular embodiments only and is not intended to be limiting. As used herein, the singular forms “a,” “an,” and “the” are intended to include the plural forms as well, unless the context clearly indicates otherwise. As used herein, the term “and/or” includes any and all combinations of one or more of the associated listed items. The term “or” means “and/or.” Expressions such as “at least one of” when preceding a list of elements, modify the entire list of elements and do not modify the individual elements of the list.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Disclosed herein is a method that comprises using the solid state solvation (SSS) effect to tune fluorescent emitters such as, for example, thermally activated thermally delayed fluorescence (TADF) organic light emitting diode (OLED) emitters (hereinafter TADF emitter) to modulate their small singlet-triplet energy gap (ΔE_{ST}). Put another way, the codopant is operative to modulate a singlet-triplet (S₁-T₁) energy gap of the TADF emitter in a solid state. In an embodiment, the codopant reduces the singlet-triplet (S₁-T₁) energy gap of the TADF emitter in the solid state.

The method comprises adding a small molecule polar codopant (hereinafter “polar codopant”) to a host matrix that contains a TADF emitter to tune the ΔE_{ST} for a desired performance. Since the ΔE_{ST} energy gap of TADF emitters is approximately 0 to 300 milli-electron volts (meV), which is on the same order of magnitude as the practical tuning range of SSS (which is approximately 100 meV), the addition of a polar or polarizable codopant to a host matrix that contains a TADF emitter makes this a useful pairing to enable emission fine tuning.

Disclosed herein too is a composition that contains a polar or polarizable codopant and a host matrix that contains a fluorescent emitter. The host matrix comprises a non-polar material that is chemically different from the TADF emitter. The use of polar moieties (in the polar or polarizable codopant) within the host matrix permits interactions with the polarized charge transfer excited state of the TADF emitter to stabilize its singlet energy and hence to reduce the ΔE_{ST} of the TADF emitter. TADF emitters are designed to have an intramolecular charge transfer state in order to yield a small ΔE_{ST} by minimizing the exchange interaction, which directly determines ΔE_{ST}. This ΔE_{ST} gap controls TADF emitter performance and it is desirable for this gap to be balanced to achieve a small but non-zero value in order to have efficient reverse intersystem crossing, while maintaining enough spatial overlap between electron and hole wavefunctions to have efficient emission from the singlet state.

Polar moieties within the host matrix interact with the polarized charge transfer excited state of the TADF emitter to stabilize its singlet energy, and hence decrease the ΔE_{ST} controllably as the polarity of the host matrix is varied. By changing the molar or weight ratio of the polar codopant to the nonpolar host, a determination can be made about the optimal polarity corresponding to the optimal TADF emitter gap size for efficient reverse intersystem crossing and radiative emission from the singlet state. Reverse intersystem crossing (RISC) is defined as a process of energy transfer from the excited triplet state back to the excited singlet.

According to an embodiment, SSS-tuning of TADF OLED emitters is used to modulate ΔE_{ST}. Solvatochromism can take place in the solid state in solid glassy matrices and is referred to as solid state solvation (SSS). This effect is analogous to solution-state solvatochromism. After excitation of an organic solute to a polar excited state, other polar small molecules within a glassy matrix can rotate in space to locally orient their dipole moments and stabilize the excited state. Subsequently, increasing the polarizability of the matrix can increase the magnitude of the stabilization and hence the magnitude of the red shift of the emission. This effect is pronounced for solutes with charge-transfer (CT) excited states, which intrinsically have a large change in polarity after excitation from the ground state to the CT singlet excited state. SSS may be used to control the photophysical properties of emitters with CT excited states to optimize the properties of an emission layer.

Thermally activated delayed fluorescence (TADF) organic light-emitting diode (OLED) emitters have a SSS-active CT singlet excited state that can minimize the exchange interaction to produce an electronic structure with a small singlet-triplet energy gap (ΔE_{ST}). The lowest energy ¹CT state can be achieved through a molecular design that incorporates donor-acceptor complexes that as a byproduct of their structure can also feature a locally-excited singlet (¹LE) localized on the donor unit that can couple with the ¹CT state. The small ΔE_{ST} can enable efficient harvesting of electrogenerated triplets through thermally activated reverse intersystem crossing, allowing TADF OLED devices to reach internal quantum efficiencies of up to 100%.

Disclosed herein too is an emission layer that includes a host matrix comprising a host material; a thermally activated delayed fluorescence emitter, wherein the host matrix and the emitter are different from each other; and a codopant comprising a small molecule that has a different dipole moment from that of a molecule of the host material. In one embodiment, the host material has a polarity (i.e., a dipole moment) that is greater than the codopant polarity. In another embodiment, the host material has a polarity that is lower than the codopant polarity. A polarizable molecule is one that can be dynamically polarized by an electric or an electromagnetic field. This field can be generated externally or also by the charge density distribution of an individual molecule, such as a TADF emitter.

The host matrix material can be an organic polymer, a ceramic or a small molecule that has a polarizability that is different from that of the codopant. In an embodiment, the host matrix material is less polar, or alternatively, less polarizable than the codopant. In another embodiment, the host matrix material is more polar, or alternatively, more polarizable than the codopant. Polarity is a separation of electric charge leading to a molecule or its chemical groups having an electric dipole or multipole moment. Polar molecules contain polar bonds due to a difference in electronegativity between the bonded atoms. A polar molecule with two or more polar bonds has an asymmetric geometry so that the bond dipoles do not cancel each other. The molecules of the codopant generally have a larger dipole moment or induced dipole moment than the molecules of the host matrix material.

In an embodiment, it is desirable for the host material to conduct charge or to be a semiconductor. In short, the host material is capable of transporting charges—it is a charge transporter. It is desirable for the triplet energy of the host matrix material to be larger than that of the emitter. Insulating polymers may therefore be doped to make them semiconducting when used in the composition. In an embodiment, the host material has an electrical volume resistivity less than about 1×10¹¹ ohm-cm.

In an embodiment, it is desirable for the organic polymer or small molecule to be optically transparent. It is desirable for the organic polymer or small molecule to have an optical transparency of at least 75%, preferably at least 85%, and more preferably at least 95%, for a film having a thickness of 1 to 200 nanometers. In an embodiment, the haze should be less than 20%, preferably less than 10%, and more preferably less than 5%, for a film having a thickness of less than 1 to 200 nanometers. It is desirable for the polymer or small molecule film to be amorphous although semi-crystalline polymers and crystalline materials may also be used.

In an embodiment, it is desirable for the organic polymer or small molecule to have a dielectric constant of about 1.5 to 4 when measured at a frequency of 1 kHz to 10 MHz.

Organic polymers used in the spaced features and/or the surface can be may be selected from a wide variety of conducting or thermoplastic polymers, blend of conducting or thermoplastic polymers, thermosetting polymers, or blends of thermoplastic polymers with thermosetting polymers. The organic polymer may also be a blend of polymers, copolymers, terpolymers, or combinations comprising at least one of the foregoing organic polymers. The organic polymer can also be an oligomer, a homopolymer, a copolymer, a block copolymer, an alternating block copolymer, a random polymer, a random copolymer, a random block copolymer, a graft copolymer, a star block copolymer, a dendrimer, a polyelectrolyte (polymers that have some repeat groups that contain electrolytes), a polyampholyte (a polyelectrolyte having both cationic and anionic repeat groups), an ionomer, or the like, or a combination comprising at last one of the foregoing organic polymers. The organic polymers have number average molecular weights greater than 10,000 grams per mole, preferably greater than 20,000 g/mole and more preferably greater than 50,000 g/mole.

Examples of the organic polymers are polyacetals, polyolefins, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyphthalides, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polyethylene terephthalate, polybutylene terephthalate, polyurethane, polytetrafluoroethylene, perfluoroelastomers, fluorinated ethylene propylene, perfluoroalkoxyethylene, polychlorotrifluoroethylene, polyvinylidene fluoride, polysiloxanes, polyphenylenevinylenes or the like, or a combination comprising at least one of the foregoing organic polymers.

Examples of polyelectrolytes are polystyrene sulfonic acid, polyacrylic acid, pectin, carrageenan, alginates, carboxymethylcellulose, polyvinylpyrrolidone, or the like, or a combination comprising at least one of the foregoing polyelectrolytes.

Examples of thermosetting polymers suitable for use as hosts in emissive layer include epoxy polymers, unsaturated polyester polymers, polyimide polymers, bismaleimide polymers, bismaleimide triazine polymers, cyanate ester polymers, vinyl polymers, benzoxazine polymers, benzocyclobutene polymers, acrylics, alkyds, phenol-formaldehyde polymers, novolacs, resoles, melamine-formaldehyde polymers, urea-formaldehyde polymers, hydroxymethylfurans, isocyanates, diallyl phthalate, triallyl cyanurate, triallyl isocyanurate, unsaturated polyesterimides, or the like, or a combination comprising at least one of the foregoing thermosetting polymers.

Examples of blends of thermoplastic polymers include acrylonitrile-butadiene-styrene/nylon, polycarbonate/acrylonitrile-butadiene-styrene, acrylonitrile butadiene styrene/polyvinyl chloride, polyphenylene ether/polystyrene, polyphenylene ether/nylon, polysulfone/acrylonitrile-butadiene-styrene, polycarbonate/thermoplastic urethane, polycarbonate/polyethylene terephthalate, polycarbonate/polybutylene terephthalate, thermoplastic elastomer alloys, nylon/elastomers, polyester/elastomers, polyethylene terephthalate/polybutylene terephthalate, acetal/elastomer, styrene-maleicanhydride/acrylonitrile-butadiene-styrene, polyether etherketone/polyethersulfone, polyether etherketone/polyetherimide polyethylene/nylon, polyethylene/polyacetal, or the like.

Polymers that can be used in the emissive layer also include biodegradable materials. Suitable examples of biodegradable polymers are as polylactic-glycolic acid (PLGA), poly-caprolactone (PCL), copolymers of polylactic-glycolic acid and poly-caprolactone (PCL-PLGA copolymer), polyhydroxy-butyrate-valerate (PHBV), polyorthoester (POE), polyethylene oxide-butylene terephthalate (PEO-PBTP), poly-D,L-lactic acid-p-dioxanone-polyethylene glycol block copolymer (PLA-DX-PEG), or the like, or combinations comprising at least one of the foregoing biodegradable polymers.

Exemplary polymers are polystyrene, polycarbonate, polymethylmethacrylate, polyetherimides, polyimides, copolymers of ethylene and α-olefins, copolymers of propylene and α-olefins, polyesters such as polyethylene terephthalate, polybutylene terephthalate, or the like, or a combination thereof.

In an embodiment, the host material may be a small molecule. In an embodiment, a small molecule is defined as being a molecule having less than 4 repeat units, preferably less than 3 repeat units, and more preferably less than 2 repeat units. The small molecule is defined as having a number molecular weight of less than 10,000 g/mole, preferably less than 5,000 g/mole, and more preferably less than 1,000 g/mole.

In an embodiment, it is desirable for such small molecule host material or for the polymeric host material to be optically transparent. In an embodiment, it is desirable for a host material film comprising the small molecule or the polymeric material to be optically transparent having an optical transparency of at least 75%, preferably at least 85%, and more preferably at least 95% when it has a thickness of 1 to 200 nanometers. In an embodiment, the haze should for the film comprising small molecules may be less than 20%, preferably less than 10%, and more preferably less than 5% when it has a thickness of less than 1 to 200 nanometers. It is desirable for a solid manufactured from the small molecule to be amorphous although semi-crystalline or crystalline forms of the small molecule may be used as the host. The small molecules preferably have melting points of 0 to 400° C., preferably 23 to 200° C., and more preferably 50 to 150° C. In other words, it is desirable for the host small molecule to be a solid at room temperature (23° C.).

It is desirable for the host material to have a dipole moment of 0 to 6 Debye, 1 to 5 Debye and 2 to 4 Debye and for the codopant to have a higher dipole moment than that of the host material.

Adding different groups to the donor or acceptor parts of the TADF molecule will change the singlet or triplet energy and hence the ΔEₛₜ and the TADF properties. This could be electron donating or withdrawing groups of a wide variety. Adding heteroatoms can also change spin-orbit coupling to alter the rates for intersystem crossing and hence the TADF efficiency. Changing from ortho- to meta-substitution of a donor-acceptor couple can have a large effect. Additionally, substituent groups (e.g., alkyl, cycloalkyl, aryl, and the like) may be added to alter the steric hindrance of a rotation along the dihedral angle between the donor and acceptor units to change the value of this angle in an equilibrium geometry and hence the electronic overlap and ΔEₛₜ.

The small molecule host material may be selected from a substituted or unsubstituted carbazole compound, a substituted or unsubstituted thiophene compound, a substituted or unsubstituted sulfonyl compound, a substituted or unsubstituted phosphino compound, a substituted or unsubstituted phosphoryl compound, a substituted or unsubstituted nitrile compound, a substituted or unsubstituted fluorene compound, a substituted or unsubstituted triazine compound, a substituted or unsubstituted phenoxazine compound, a substituted or unsubstituted quinazoline compound, a substituted or unsubstituted pyridine compound, or a combination thereof. In an embodiment, the nonpolar host material is a phenyl carbazole of the formula (1):

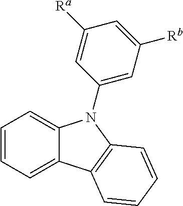

wherein R^{a} and R^{b} are each independently hydrogen, a phosphine oxide, a carbazole, or a C₆ to C₂₄ aryl.

Other small molecule host materials are shown below in the formulas (2) to (26) below

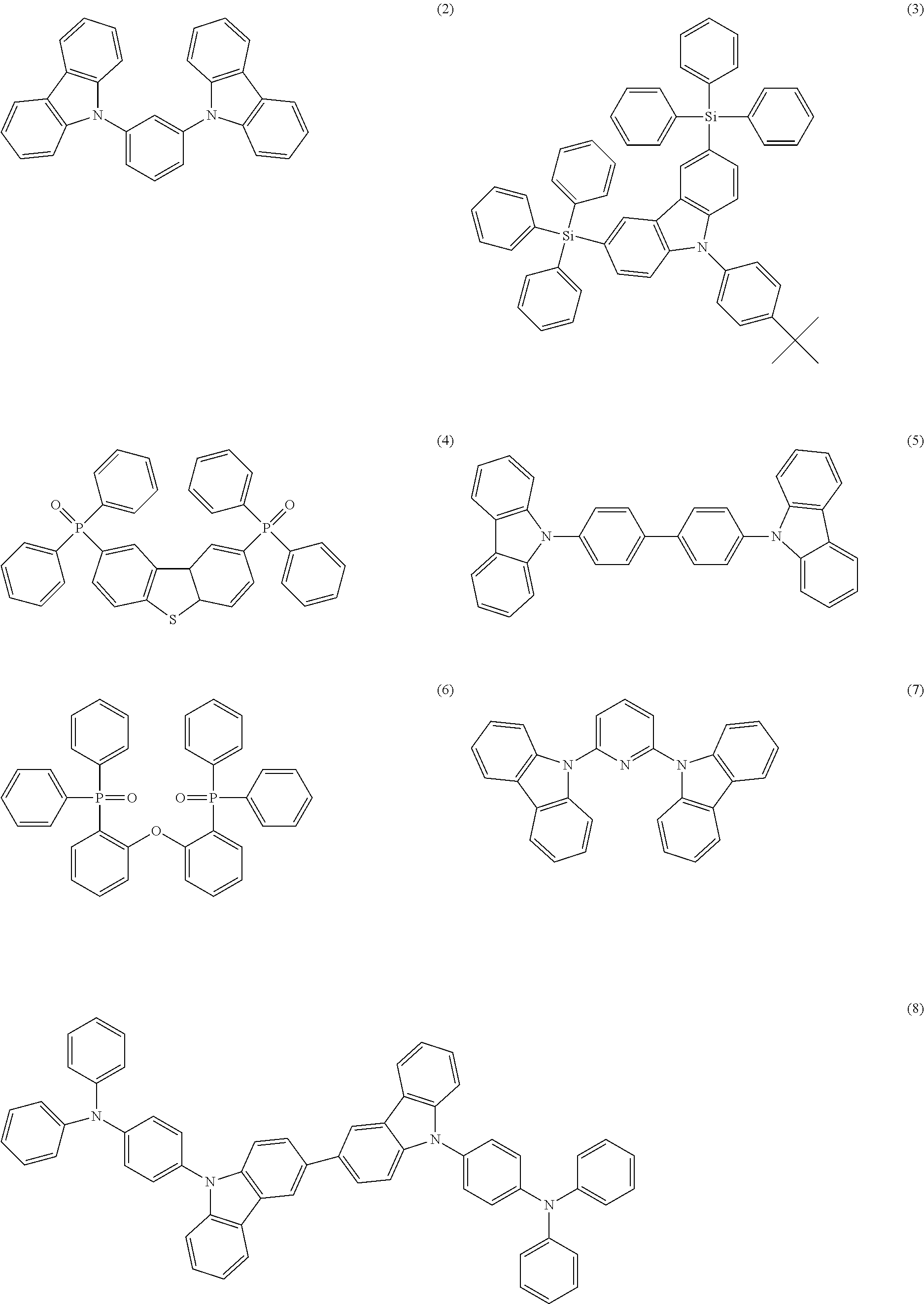

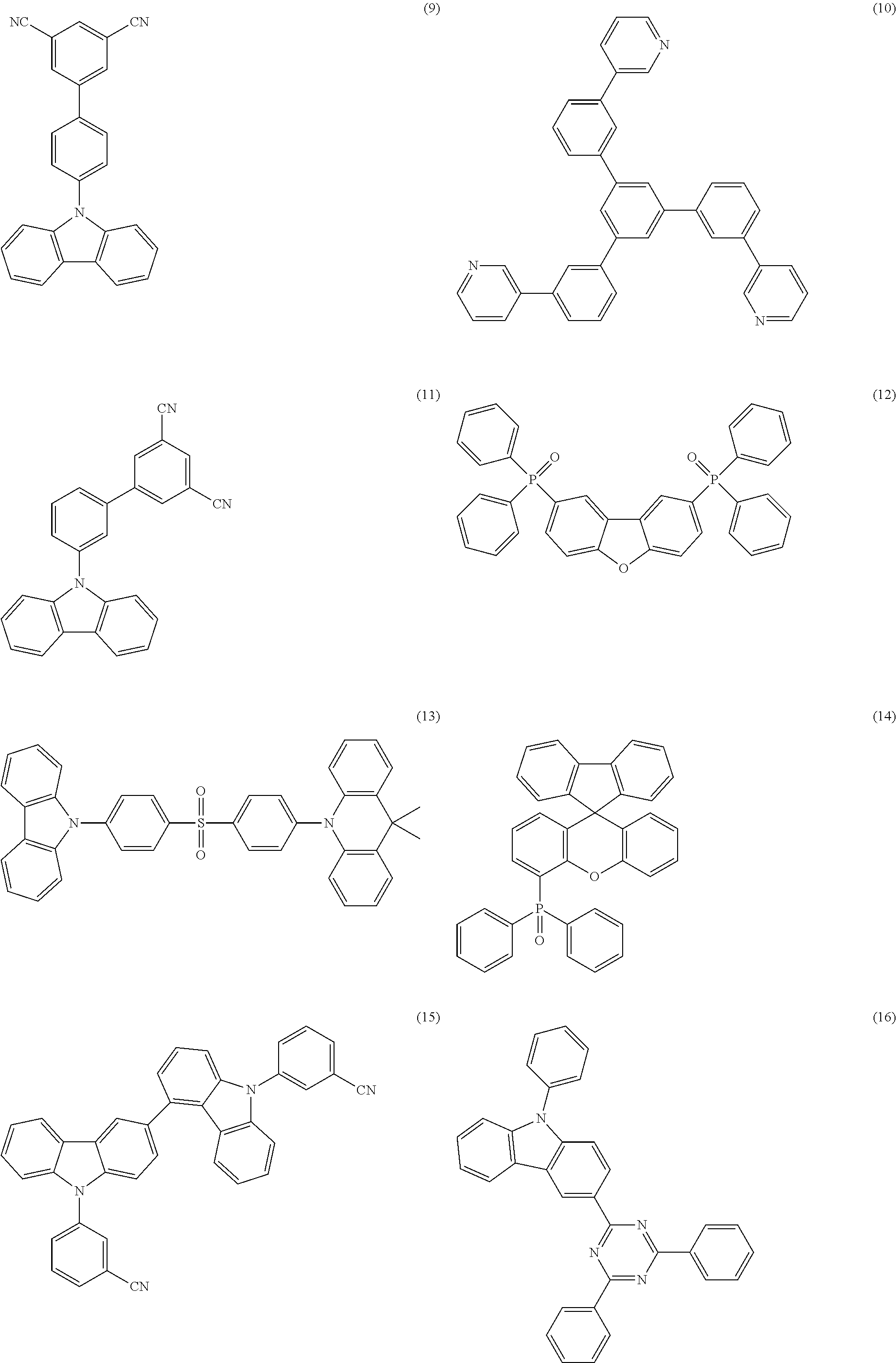

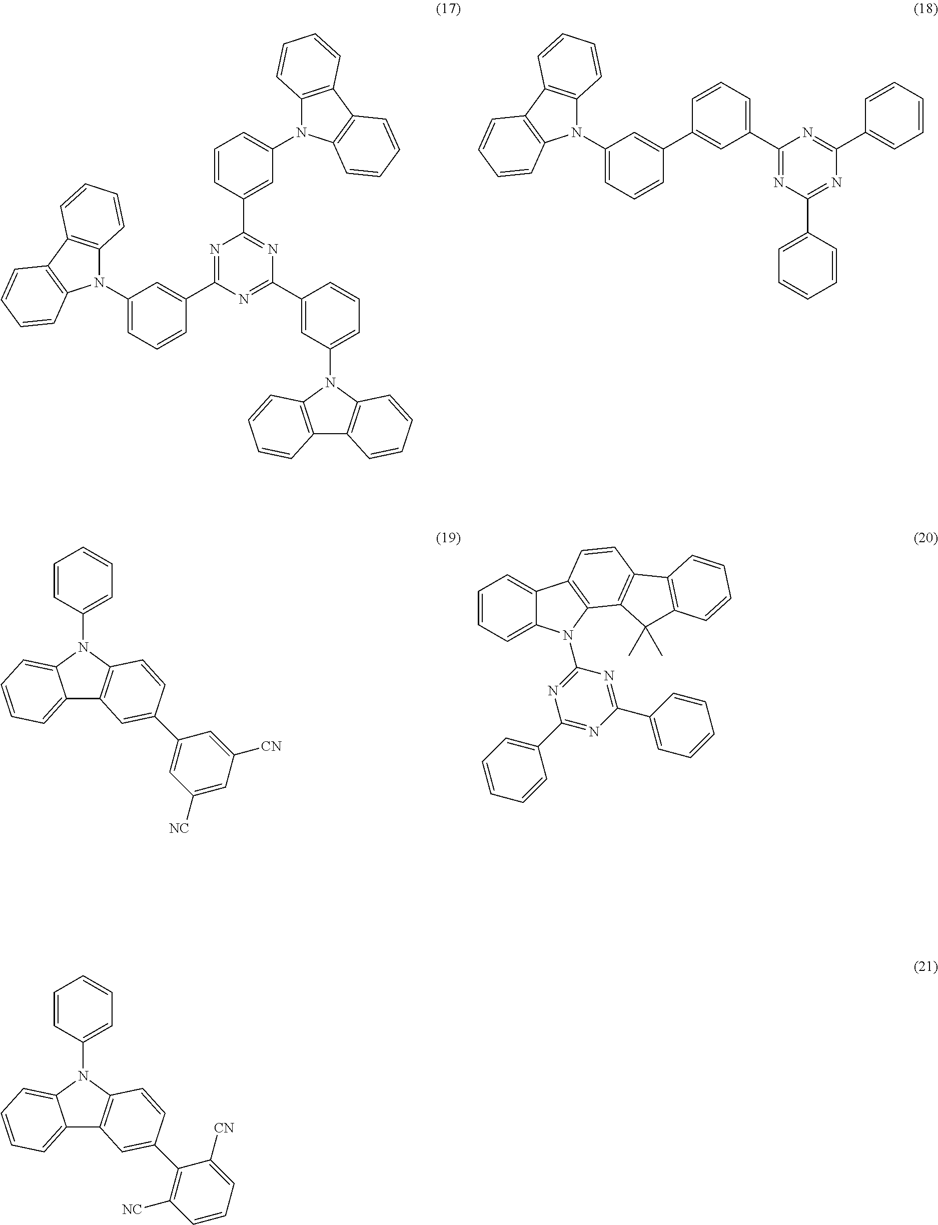 [SMILES: c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1 ; c1ccc(-c2nc(-c3ccccc3)nc(-c3cccc(-c4cccc(-n5c6ccccc6c6ccccc65)c4)c3)n2)cc1 ; N#Cc1cc(C#N)cc(-c2ccc3c(c2)c2ccccc2n3-c2ccccc2)c1 ; CC1(C)c2ccccc2-c2ccc3c4ccccc4n(-c4nc(-c5ccccc5)nc(-c5ccccc5)n4)c3c21 ; N#Cc1cccc(C#N)c1-c1ccc2c(c1)c1ccccc1n2-c1ccccc1]

All of the small molecule host material shown in the formulas (2) to (21) may be substituted or unsubstituted if desired. The host material is present in an amount of 40 to 99 weight percent, preferably 60 to 95 wt %, and more preferably 70 to 90 wt % based on the total weight of the emission layer.

The thermally activated delayed fluorescence emitter (sometimes referred to as a dopant) is a small molecule having an average molecular weight of less than 10,000 g/mole, preferably less than 5,000 g/mole, and preferably less than 1,000 g/mole. The thermally activated delayed fluorescence emitter has less than 4 repeat units, preferably less than 3 repeat units and more preferably less than 2 repeat units. It is desirable for the thermally activated delayed fluorescent emitter to be capable of being compatible with and being intimately blendable with the host material. The thermally activated delayed fluorescence emitter can emit blue light, red light or green light.

According to an embodiment, an energy gap between a singlet energy and a triplet energy of the emitter (a single-triplet energy state of the emitter) is about 5 milli-electron volts to about 150 milli-electron volts, preferably about 10 milli-electron volts to about 100 milli-electron volts, more preferably about 20 milli-electron volts to about 90 milli-electron volts.

In an embodiment, the thermally activated delayed fluorescence emitter is selected from a substituted or unsubstituted sulfonyl compound, a substituted or unsubstituted carbazole compound, a substituted or unsubstituted triazole compound, a substituted or unsubstituted acridine compound, a substituted or unsubstituted triazine compound, a substituted or unsubstituted nitrile compound, a substituted or unsubstituted phenylpyridine compound, a substituted or unsubstituted phenoxazine compound, a substituted or unsubstituted fluorene compound, a substituted or unsubstituted oxadiazole compound, a substituted or unsubstituted xanthene compound, a substituted or unsubstituted phenylamino compound, a substituted or unsubstituted phenazine compound, a substituted or unsubstituted arylboron-containing compound, an organocopper compound, an organoplatinum compound, an organoiridium compound, an organopalladium compound, or a combination thereof.

Examples of thermally activated delayed fluorescence emitters are shown in the formula (22) below.

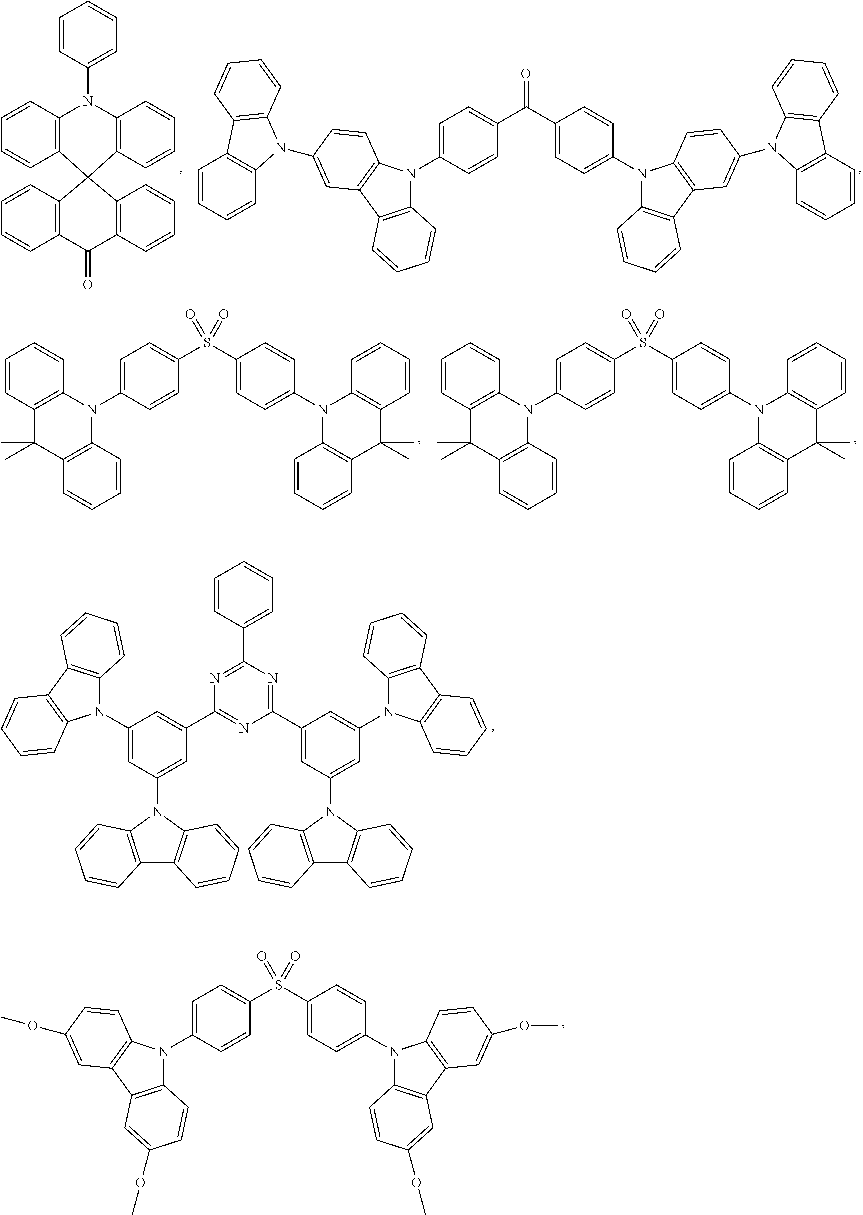

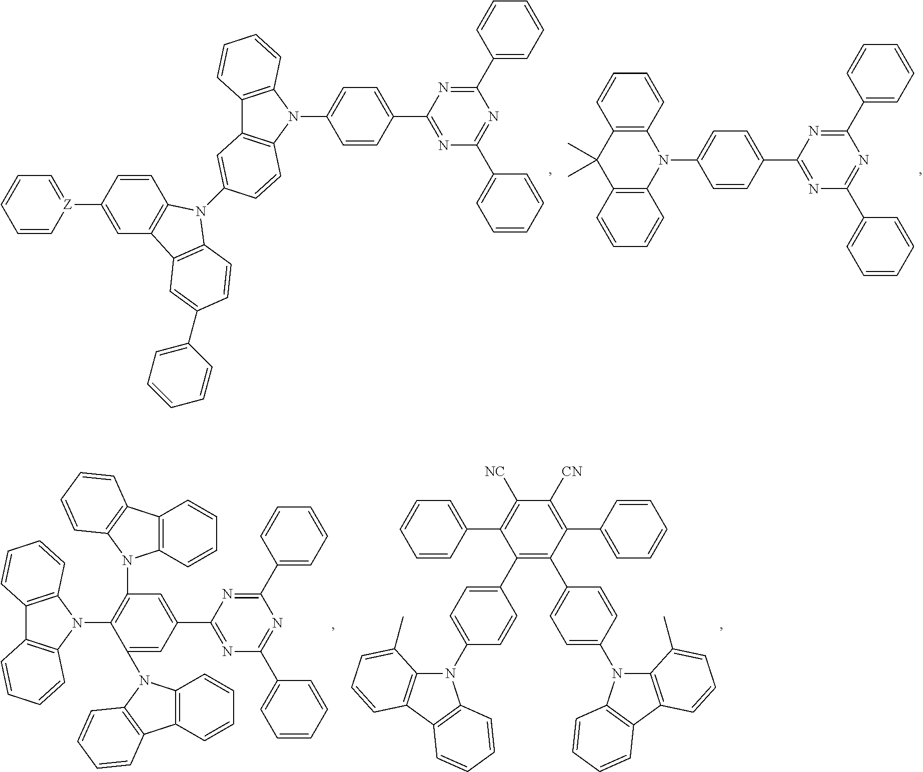

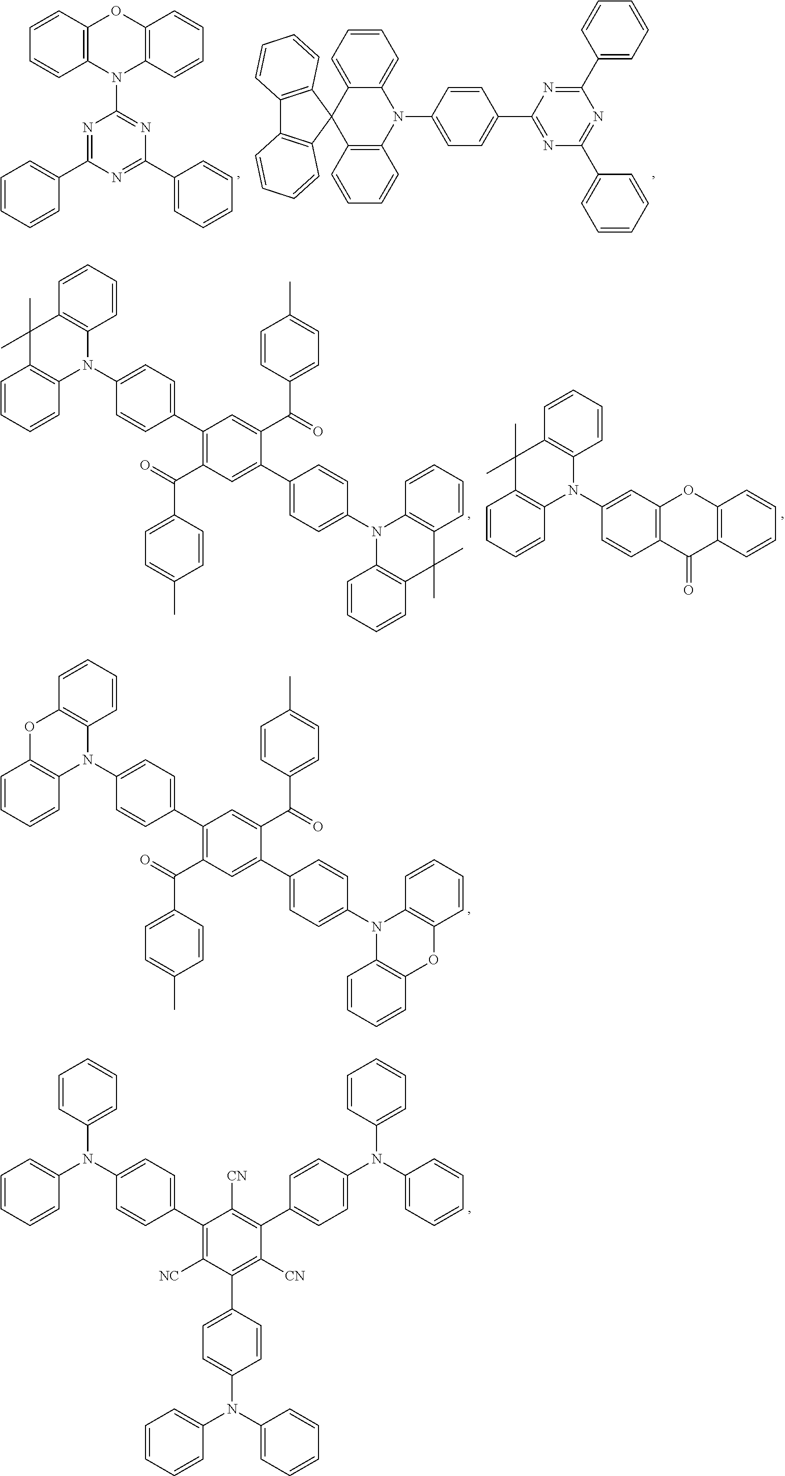

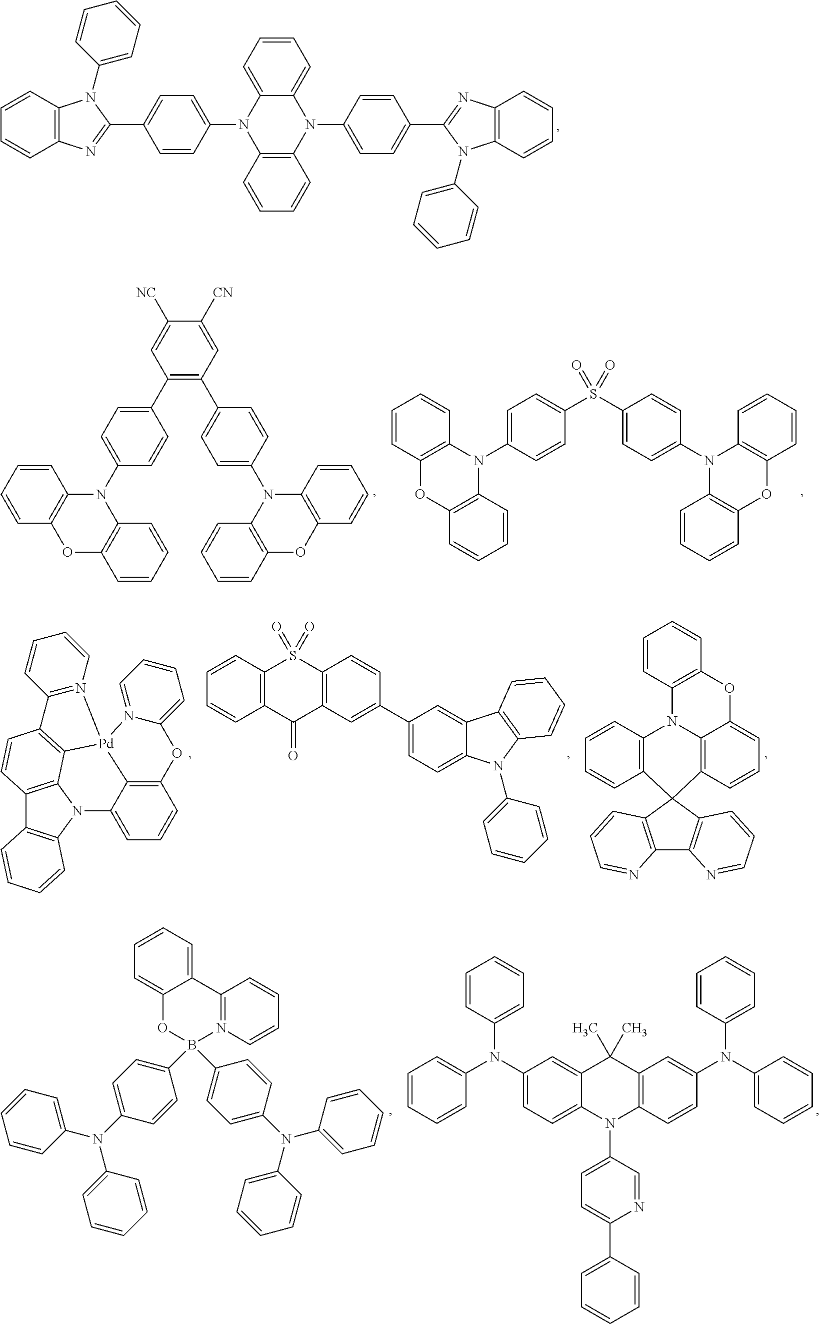

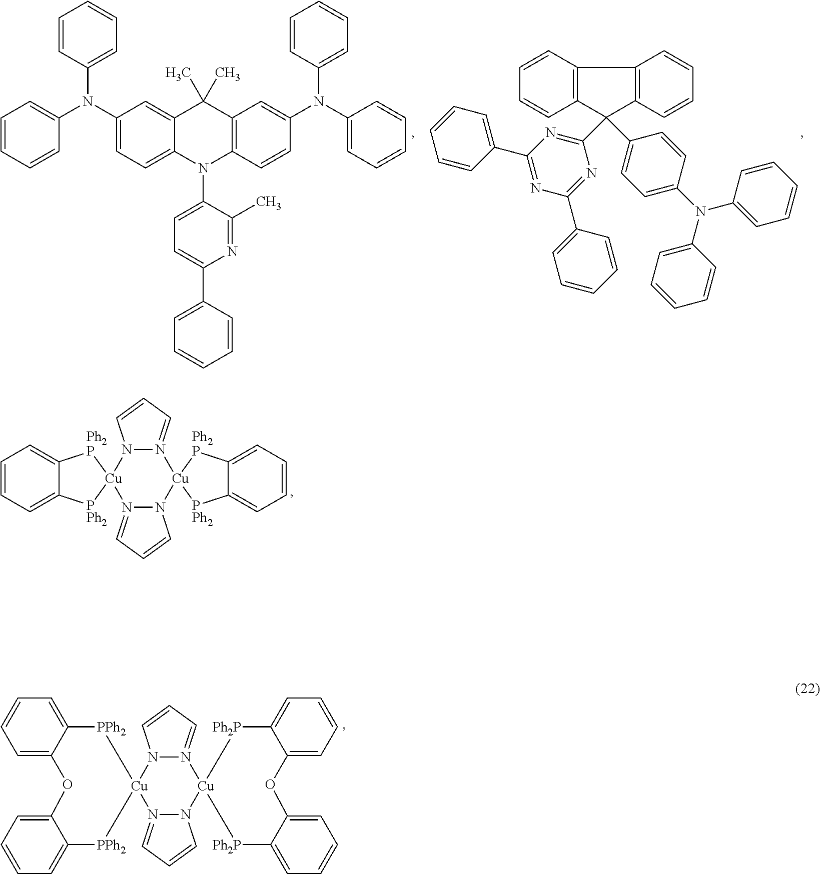

or combinations thereof.

In an exemplary embodiment, the thermally activated delayed fluorescence emitter is 2,5-bis(4-(10H-phenoxazin-10-yl)phenyl)-1,3,4-oxadiazole (2PXZ-OXD) of the formula (23):

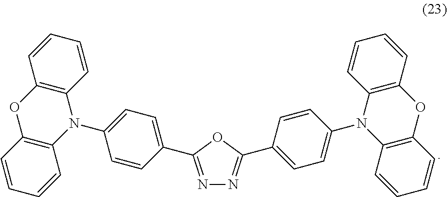 [SMILES: c1ccc2c(c1)Oc1ccccc1N2c1ccc(-c2nnc(-c3ccc(N4c5ccccc5Oc5ccccc54)cc3)o2)cc1]

In the emission layer, the thermally activated delayed fluorescence emitter is present in an amount of about 1 weight percent to about 30 weight percent, preferably about 2 weight percent to about 25 weight percent, more preferably about 3 weight percent to about 20 weight percent, based on a total weight of the emission layer.

The polar or polarizable small molecule facilitates a reduction in an energy gap between an excited singlet energy and an excited triplet energy of the emitter when disposed in the emission layer. In an embodiment, the polar or polarizable small molecule (sometimes referred to as a dopant) has a number average molecular weight of less than 10,000 g/mole, preferably less than 5,000 g/mole, and preferably less than 1,000 g/mole. The polar or polarizable codopant has less than 4 repeat units, preferably less than 3 repeat units and more preferably less than 2 repeat units. It is desirable for the codopant to be capable of being compatible with and being intimately blendable with the host material and the thermally activated delayed fluorescence emitter.

In an embodiment, the polar or polarizable small molecule is selected from a benzoate compound, a hydroxyquinoline compound, a cyclic anhydride compound, a pyrimidinone compound, a dialkylaniline compound, a dione compound, a polycyclic nitrile compound, a quinolinone compound, or a combination thereof.

In an embodiment, the polar or polarizable small molecule is at least one selected from a substituted or unsubstituted C₆-C₃₀ cyclic anhydride and a substituted or unsubstituted C₅-C₂₀ cyclic dione. In an embodiment, the polar or polarizable small molecule is at least one selected from camphoric acid anhydride, cyclohexadione, diphenic acid anhydride, methylbenzoate, dimethylaniline, 8-hydroxyquinoline, isatoic anhydride, maleic anhydride, bromomaleic anhydride, phenylmaleic anhydride, phenylsuccinic anhydride, 2-phenylbutyric acid anhydride, 2-phenylglutaric anhydride, 4-tert-butylphthalic anhydride, 2-(triphenylphosphoranylidene)succinic anhydride, p-toluenesulfonic anhydride, 1-Phenyl-2,3-naphthalenedicarboxylic anhydride, dodecenylsuccinic anhydride, 1,3-dimethyl-3,4,5,6-tetrahydro-2-pyrimidinone, 1,4-dihydroisoquinolin-3(2H)-one, or a combination thereof.

In another embodiment, the polar or polarizable small molecule may be a zwitterion or an organic salt. A zwitterion is a neutral molecule with both positive and negative electrical charges. Examples of zwitterions are amino acids. Examples of a zwitterion and an organic salt are shown below in the formula (24)

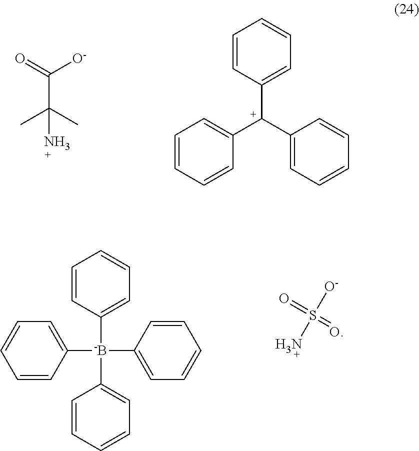

In the emission layer, the polar or polarizable small molecule is present in an amount of about 0.01 weight percent to about 45 weight percent, preferably about 0.1 weight percent to about 30 weight percent, more preferably about 1 weight percent to about 20 weight percent, based on the total weight of the emission layer.

According to an embodiment, the emission layer has a prompt photoluminescence lifetime that is longer than a prompt photoluminescence lifetime of a comparable emission layer that does not comprise the codopant. In an embodiment, the emission layer has a prompt photoluminescence lifetime that is about 0.1 nanosecond to about 100 nanoseconds, preferably about 2 nanoseconds to about 75 nanoseconds, more preferably about 5 nanosecond to about 50 nanoseconds.

In an embodiment, the emission layer has a delayed photoluminescence lifetime that is shorter than a delayed photoluminescence lifetime of the comparable emission layer that does not comprise the codopant. In an embodiment, the emission layer has a delayed photoluminescence lifetime that is about 0.1 microsecond to about 10,000 microseconds, preferably about 1 microsecond to about 1,000 microseconds, more preferably about 100 microseconds to about 1,000 microseconds.

In an embodiment, the emission layer has a photoluminescence quantum yield that is greater than a photoluminescence quantum yield of the comparable emission layer that does not comprise the codopant. In an embodiment, the photoluminescence quantum yield is greater than about 15%, greater than about 25%, greater than about 35%, greater than about 45%, greater than about 50%, greater than about 75%, greater than about 95%, greater than about 96%, greater than about 97%, greater than about 98%, or greater than about 99%.

In an embodiment, the emission layer has a maximum intensity photoluminescence emission peak that is at a longer wavelength than a wavelength of a maximum intensity photoluminescence emission peak of the comparable emission layer that does not comprise the codopant. In an embodiment, a difference between the maximum intensity photoluminescence emission peak wavelength of the emission layer and the maximum intensity photoluminescence emission peak wavelength of the comparable emission layer that does not comprise the codopant is about 1 to 50 nm, preferably 1 to 30 nm.

In an embodiment, the emission layer has an electroluminescence quantum yield that is greater than an electroluminescence quantum yield of the comparable emission layer that does not comprise the codopant. In an embodiment, the electroluminescence quantum yield is greater than about 15%, greater than about 25%, greater than about 35%, greater than about 45%, greater than about 50%, greater than about 75%, greater than about 95%, greater than about 96%, greater than about 97%, greater than about 98%, or greater than about 99%. In an exemplary embodiment, the external quantum efficiency as determined by the directly measured output is 5 to 50%, preferably 10 to 20%.

In one embodiment, in one method of manufacturing the emission layer, the host material, the thermally activated delayed fluorescence emitter and the polar or polarizable small molecule are mixed in a suitable solvent to manufacture an emission composition. The emission composition is then disposed onto a suitable substrate.

The solvent is preferably one that can dissolve at least all of the reactants involved in the manufacture of the emission composition. Depending upon the chemistry of the host material, the thermally activated delayed fluorescence emitter and the polar or polarizable small molecule, the solvent may be a protic or an aprotic polar solvent. Aprotic polar solvents such as propylene carbonate, ethylene carbonate, butyrolactone, acetonitrile, benzonitrile, nitromethane, nitrobenzene, sulfolane, dimethylformamide, chloroform, N-methylpyrrolidone, or the like, or a combination thereof are generally desirable. Polar protic solvents such as, but not limited to, water, methanol, acetonitrile, nitromethane, ethanol, propanol, isopropanol, butanol, or the like, or a combination thereof may be used. An exemplary solvent is chloroform. The concentration of solvent is selected for convenience, film quality, and solubility of components.

The deposition of the emission layer may be conducted by spin casting, dip coating, brush painting, spray painting, electrostatic painting, vapor deposition, vacuum deposition, or a combination thereof. The emission layer may then be dried, removed from the substrate and used in a suitable device. In an embodiment, the emission layer is not removed from the substrate but other layers are disposed on the emission layer. In yet another embodiment, one or more layers are disposed on the substrate prior to disposing the emission layer on the substrate

In another embodiment, the host material, the thermally activated delayed fluorescence emitter and the polar or polarizable small molecule are mixed in a suitable solvent and extruded to manufacture the emission layer. The extrusion may be conducted in a single screw or twin screw extruder.

In yet another embodiment, the host material, the thermally activated delayed fluorescence emitter and the polar or polarizable small molecule may be dry blended (e.g., blended in the absence of a solvent or a liquid) and extruded to form the emission layer. The emission layer may then be used in a suitable device.

In yet another embodiment, vapor deposition may be used to form the emission layer. Vapor deposition is a family of processes used to deposit layers of material atom-by-atom or molecule-by-molecule on a solid surface. These processes may operate at pressures well below atmospheric pressure (i.e., vacuum) or at pressures greater than atmospheric. The deposited layers can range from a thickness of one atom up to millimeters, forming freestanding structures. Subclasses of vapor deposition include physical vapor deposition (PVD) and chemical vapor deposition (CVD).

In physical vapor deposition, vapors of the components (the host material, the fluorescent emitter, the polar and/or polarizable codopant) are evaporated in a chamber using thermal or electromagnetic energy. The vapors are disposed on a substrate in the desired ratio to form the emission layer.

In yet another embodiment, chemical vapor deposition may be used to form the emission layer. In typical chemical vapor deposition, a substrate is exposed to one or more volatile precursors, which react and/or decompose on the substrate surface to produce the desired deposit. Frequently, volatile by-products are also produced, which are removed by gas flow through the reaction chamber.

The device includes an electron-transport layer, a hole-transport layer and the emission layer. The emission layer is disposed between the electron transport layer and the hole transport layer. In an embodiment, the emission layer is in direct contact with the electron transport layer and the hole transport layer. In an embodiment, the device further includes an anode and a cathode. In an embodiment, the device can be an organic light emitting diode (OLED).

The invention is exemplified by the following non-limiting example.

### EXAMPLE

The following components are used in the examples. Polystyrene (PS) (the host material) was purchased from Sigma-Aldrich, camphoric acid anhydride (CA) (the polar molecule) was purchased from VWR, and 2,5-bis(4-(10H-phenoxazin-10-yl)phenyl)-1,3,4-oxadiazole (2PXZ-OXD) (thermally activated delayed fluorescence emitter) was purchased from Luminescence Technology Corp. All chemicals were used without further purification.

Unless specifically indicated otherwise, the amount of each component is in weight percent in the following examples, based on the total weight of the composition.

### Sample Preparation

Within a nitrogen glovebox, separate solutions of 2PXZ-OXD, CA, and PS are prepared at a concentration of 50 mg/mL in chloroform and are stirred at 35° C. for at least an hour and then allowed to return to room temperature while stirring. Quartz substrates are sonicated for 15 minutes in isopropanol before being rinsed and dried with N₂. The proper ratio of each solution is then pipetted into another vial and stirred together before spin coating at 2000 rpm for 1 minute (1500 rpm/s acceleration). Films are either encapsulated within the glovebox or remain under nitrogen purge for all measurements.

### Physical Measurement

Physical measurements were made using the tests and test methods described below. Unless indicated otherwise, all tests are the tests in effect in the year 2014.

UV-Vis absorption spectra were acquired on an Agilent Cary-100 UV. Time-resolved and steady state fluorescence measurements and photoluminescence spectroscopy were conducted with a Horiba NanoLog Spectrofluorometer. Excitation for fluorescence spectra was centered at 390 nm using a Xenon lamp. Prompt lifetimes were measured in TCSPC mode using a 310 nm NanoLED pulsed excitation source (1.2 ns pulsewidth). Delayed Lifetimes were measured using Multi-channel Scalingmode and were excited with a 310 nm SpectralLED pulsed excitation source (controllable pulse width >0.1 ms).

Quantum Yield measurements were conducted by preparing samples that were placed inside an integrating sphere (LabSphere RTC-060) and the sphere was flushed with constant nitrogen flow. Samples were excited with a Coherent Obis 375 nm laser and spectra were recorded through a SpectraPro 500i Acton research monochromator/Spectrum CCD. A calibration for the spectral throughput of the entire system was performed and applied to each spectrum.

### Example 1

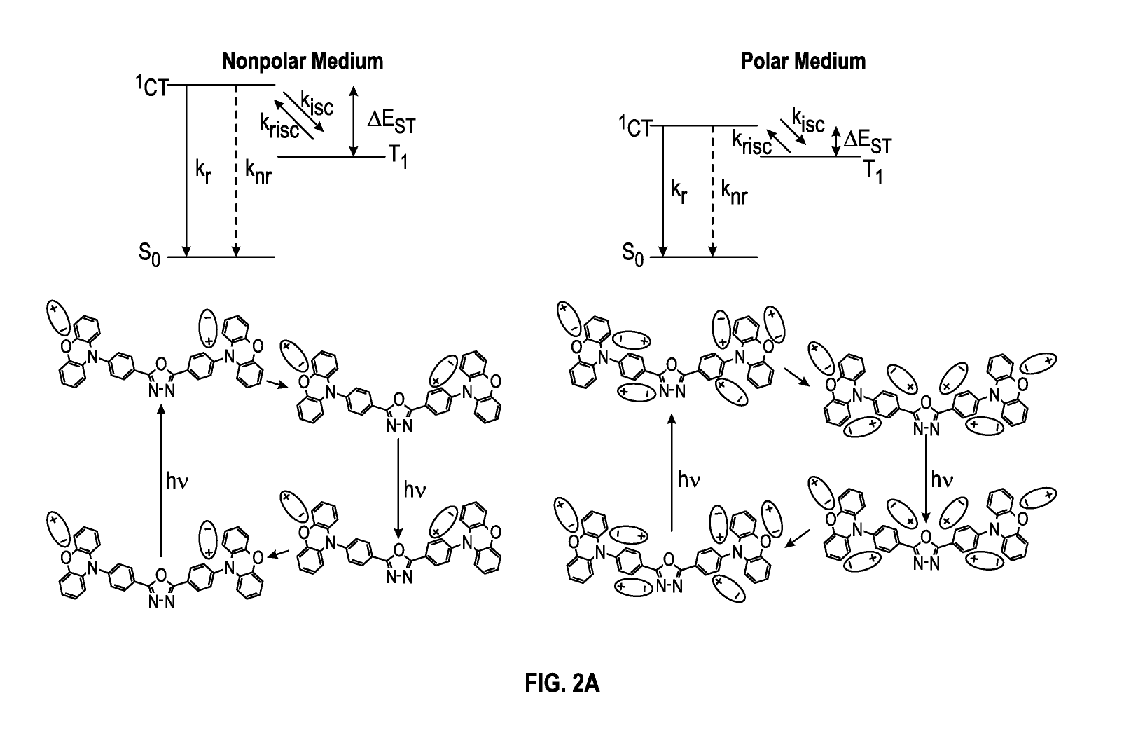

The effect of solvent polarity on the charge transfer states of 2PXZ-OXD was evaluated using photoluminescence spectroscopy. Photoluminescence spectra were obtained in cyclohexane, toluene, tetrahydrofuran, chloroform, acetone, dimethyl formamide, and acetonitrile. The solution phase 2PXZ-OXD photoluminescence spectra displayed red shifts with increasing solvent polarity, as shown in FIG. 2B. After excitation to the ¹CT state, the surrounding solvent molecules reorganized to stabilize the polarized excited state structure, resulting in a red shift in energy. This is shown in FIG. 2A, where the difference between the singlet energy of 2PXZ-OXD and the triplet energy of 2PXZ-OXD, ΔE_{ST}, decreased in polar solvents relative. The degree of the observed red shift correlated to the polarity of the solvent, allowing for control of the effective ΔE_{ST}.

### Example 2

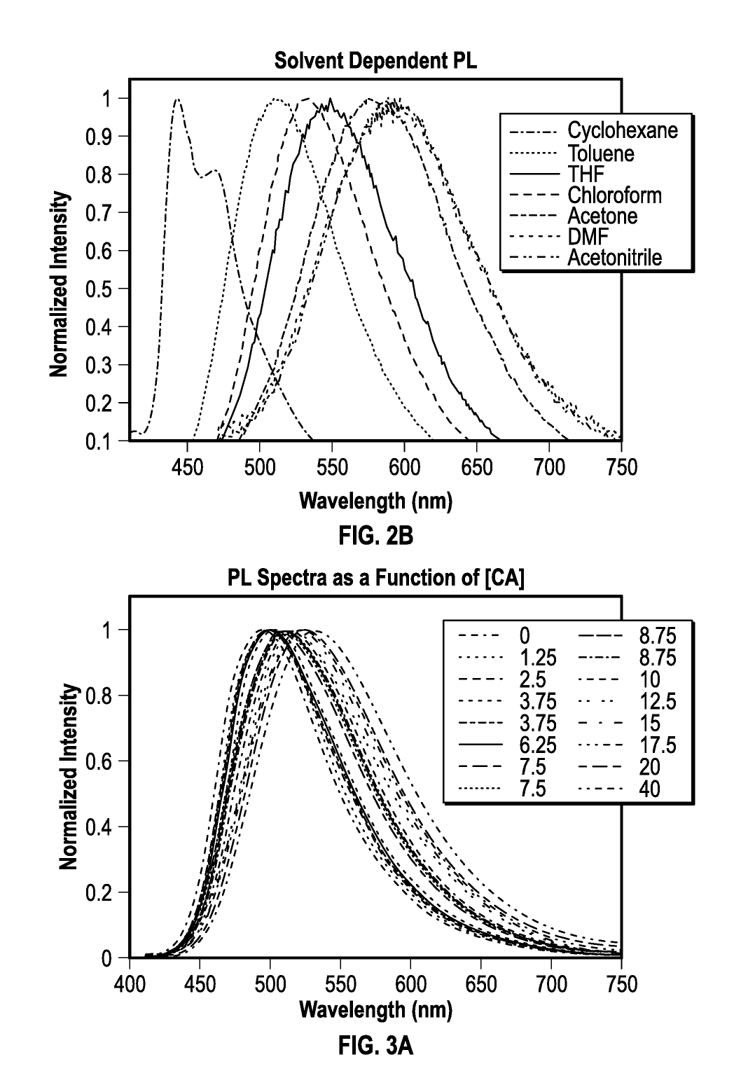

The effect of adding a co-dopant to 2PXZ-OXD was evaluated using photoluminescence spectroscopy. Addition of a small molecule, camphoric anhydride (CA), as a co-dopant in a polystyrene host matrix induced a red-shift of the photoluminescence spectrum as a function of concentration in the solid state, as shown in FIG. 3A. The spectra were obtained using 0 to 40 wt % CA, and a plot of the photoluminescent peak (nm) versus the concentration of CA is shown in FIG. 3B. The three-component system allowed for tuning of the ΔE_{ST} in the model device structure, and demonstrated the multivariable interaction of the matrix host with the polar intramolecular charge transfer state (¹CT) of the guest dopant. The system can enable optimal device efficiency and color purity, and revealed pathways to optimization for efficient solution-processed OLEDs.

### Example 3

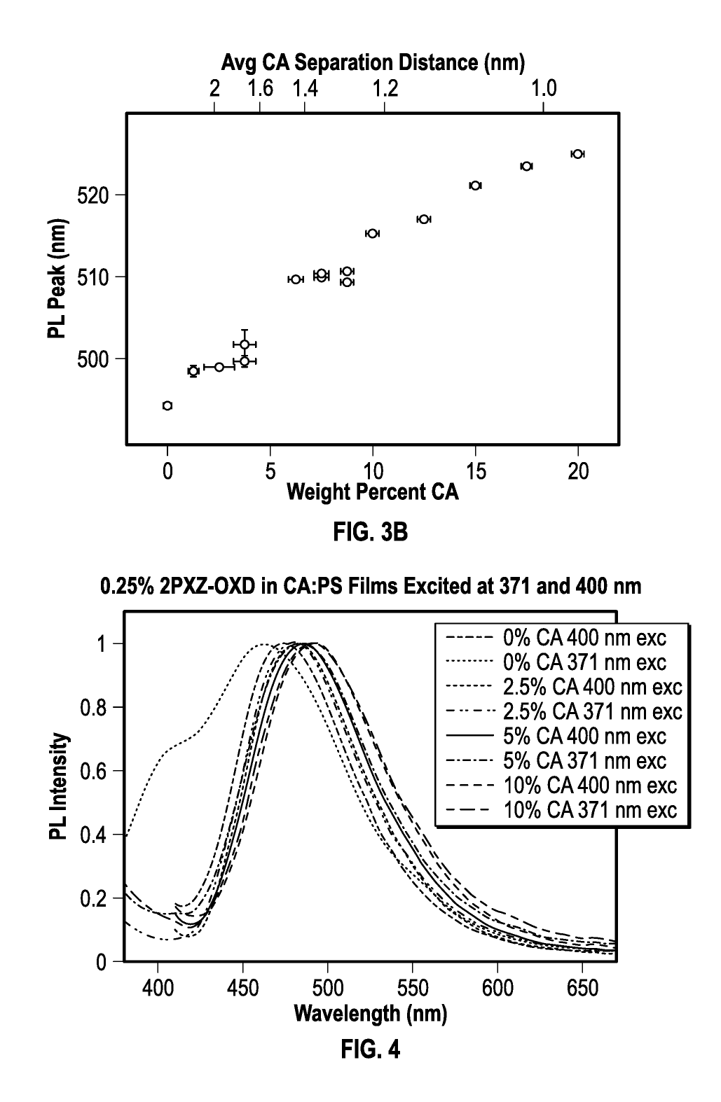

The effect of solid state solvation on a thermally activated delayed fluorescence (TADF) emitter was evaluated using photoluminescence spectroscopy. The solid state solvation effect was demonstrated using a polystyrene host matrix, CA, and 2PXZ-OXD. Photoluminescence spectra were obtained using polystyrene films comprising 0.25 wt % of 2PXZ-OXD and 0 to 10 wt % of CA. The films were excited at 371 and 400 nm, and the resulting spectra are shown in FIG. 4. The active role of CA in solvating the ¹CT state was revealed by comparing the resulting PL spectra after excitation at 400 nm to spectra after excitation at 371 nm as a function of CA concentration. In the absence of CA, a blue-shifted shoulder was evident in the PL spectra when excited at 371 nm. The corresponding incomplete relaxation to the band edge before emission indicated the incomplete solvation of the singlet state in the absence of the CA co-dopant.

### Example 4

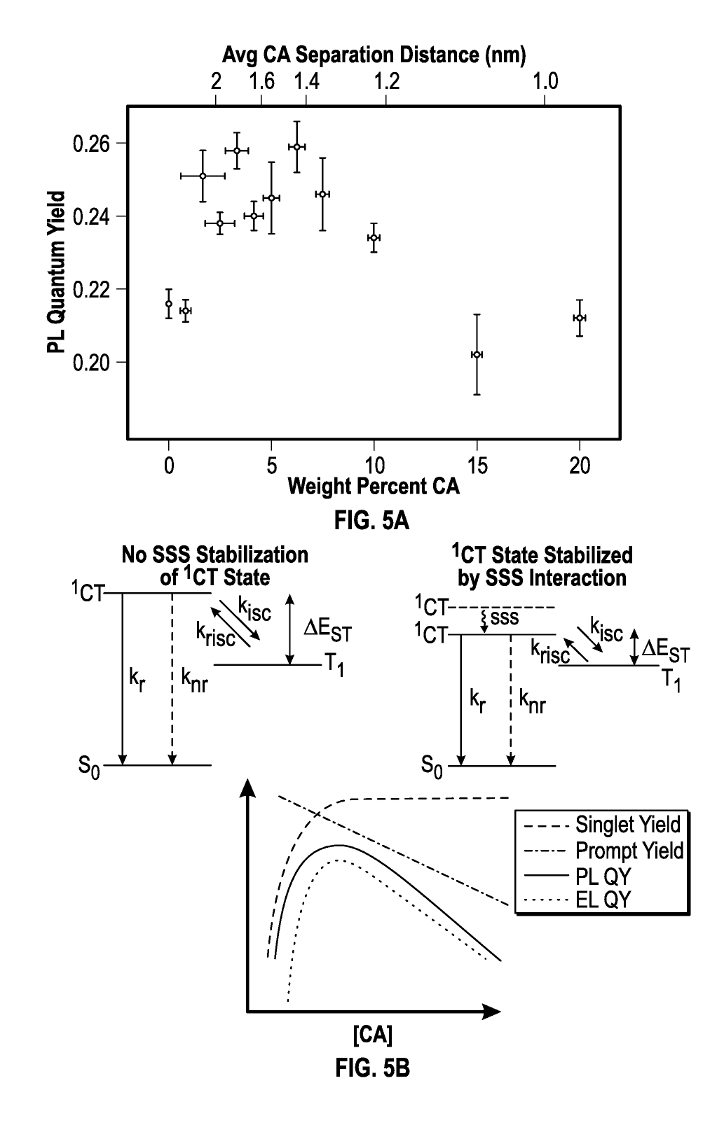

The effect of CA concentration on the quantum yield (QY) of the three-component system was evaluated using PL spectroscopy. As illustrated in FIG. 5B, a non-monotonic change in QY was observed as the concentration of CA was varied, with a maximum QY observed at about 5 wt % of CA. Two competing effects determine the QY based on the concentration of CA in the PL spectra. As the ¹CT state shifts to a lower energy as the concentration of CA increases, the mixing between the ¹LE state and the ¹CT state is decreased, and the singlet oscillator strength decreases, decreasing the QY. At the same time, higher concentrations of CA increases the efficiency of the TADF process by decreasing ΔE_{ST}, leading to a higher QY. At lower concentration of CA the benefits in improved TADF efficiency exceed the losses in oscillator strength causing the QY to initially increase before decreasing at higher concentrations of CA where the loss in oscillator strength dominates. These effects, when taken together, reveal the shapes of the observed QY curves shown in FIG. 5A.

### Example 5

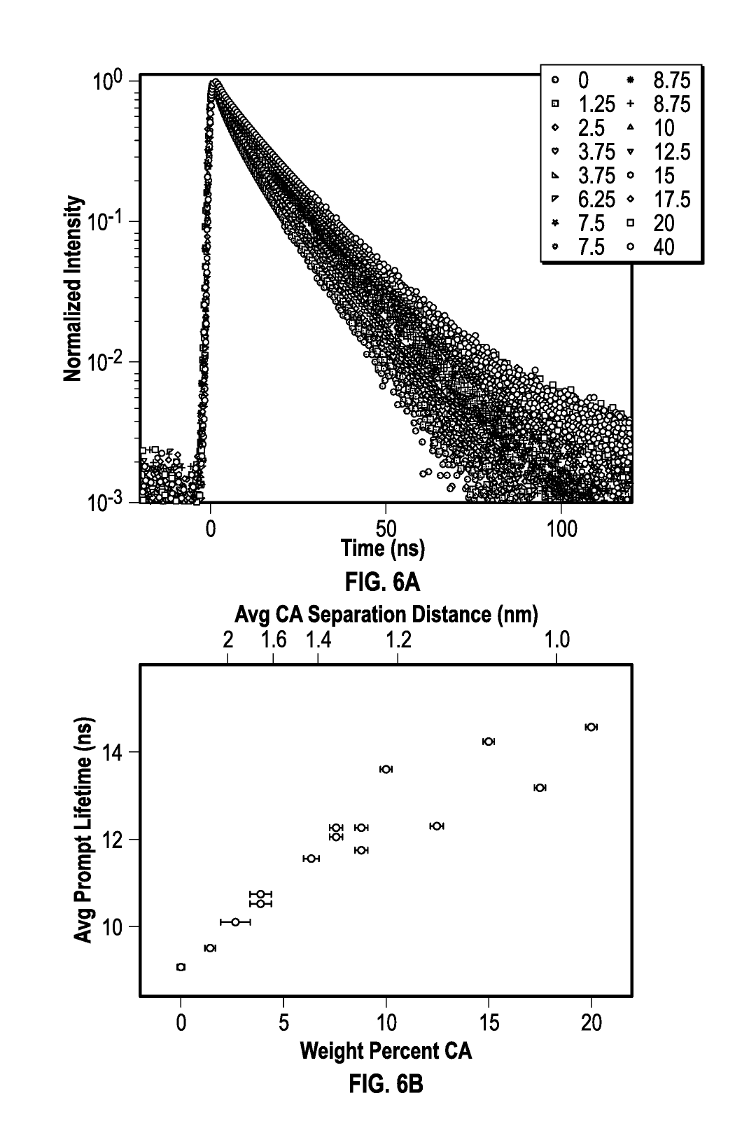

The effect of CA concentration on the average prompt lifetime of 2PXZ-OXD was evaluated using PL spectroscopy. FIG. 6A shows the rate of prompt decay for 2PXZ-OXD in the presence of 0 to 40 wt % of CA. The data is visualized in FIG. 6B, which shows that the average prompt lifetime increased with increasing concentrations of CA. As the concentration of CA is increased, the solid state solvation effect (SSSE) increased and the ΔE_{ST} decreased, suggesting that the polar small molecule co-dopant, CA, increased the average prompt lifetime as the ¹CT state was stabilized by the SSSE.

### Example 6

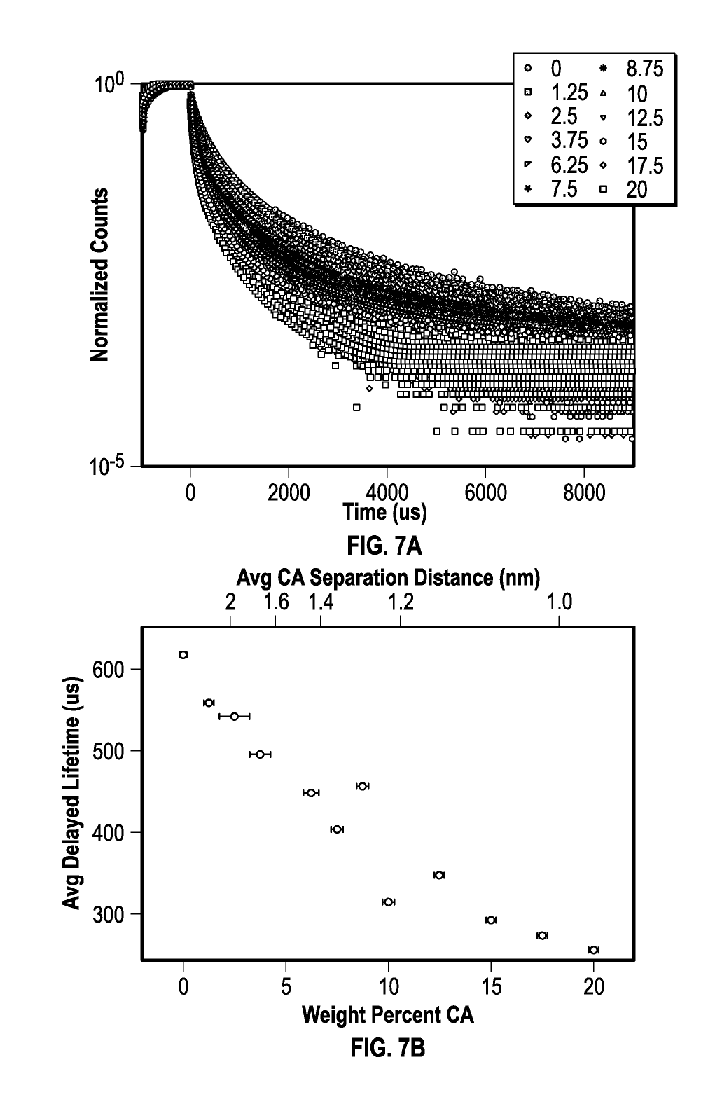

The effect of CA concentration on the average delayed lifetime of 2PXZ-OXD was evaluated using PL spectroscopy. FIG. 7A shows the rate of delayed decay for 2PXZ-OXD in the presence of 0 to 20 wt % of CA. The data is visualized in FIG. 7B, which shows that the average delayed lifetime decreased with increasing concentrations of CA. As the concentration of CA is increased, the solid state solvation effect (SSSE) increased and the ΔE_{ST} decreased, suggesting that the polar small molecule co-dopant, CA, decreased the average delayed lifetime of 2PXZ-OXD because the difference between the energy of the T₁ state and the energy of the ¹CT state decreased with increasing CA concentration.

The combined results obtained from Examples 2, 3, 4, 5, and 6 suggested that the optimal amount of CA co-doping appeared to be about 5 wt % of CA, as the QY was maximized. At 5 wt % of CA, it was observed from the prompt lifetime that the singlet state oscillator strength was not unduly compromised, while the delayed lifetime had changed more dramatically, indicating increased TADF efficiency leading to an improved QY. It was possible that the QY for the electroluminescence is more optimal at a slightly higher concentration of CA where the benefits of lower TADF lifetime can be more fully realized because of an initial 75% triplet population that does not occur with the photoexcitation of the examples.

### Example 7

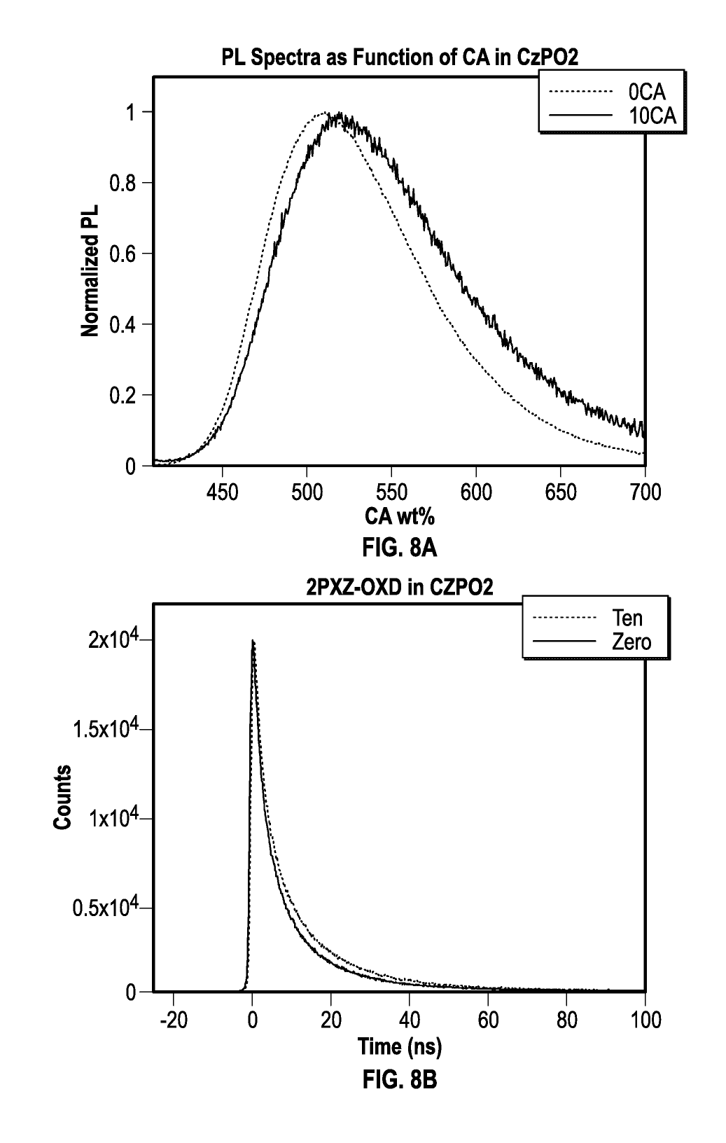

The SSSE on 2PXZ-OXD in another host matrix was evaluated using photoluminescence spectroscopy. The solid state solvation effect was demonstrated using a CzPO₂ host matrix, CA, and 2PXZ-OXD. Photoluminescence spectra were obtained using films are shown in FIG. 8A. The incorporation of 10 wt % of CA resulted in a red-shifted PL spectrum. As shown in FIG. 8B, the incorporation of 10 wt % of CA resulted in an increase in the average prompt lifetime.

### Example 8

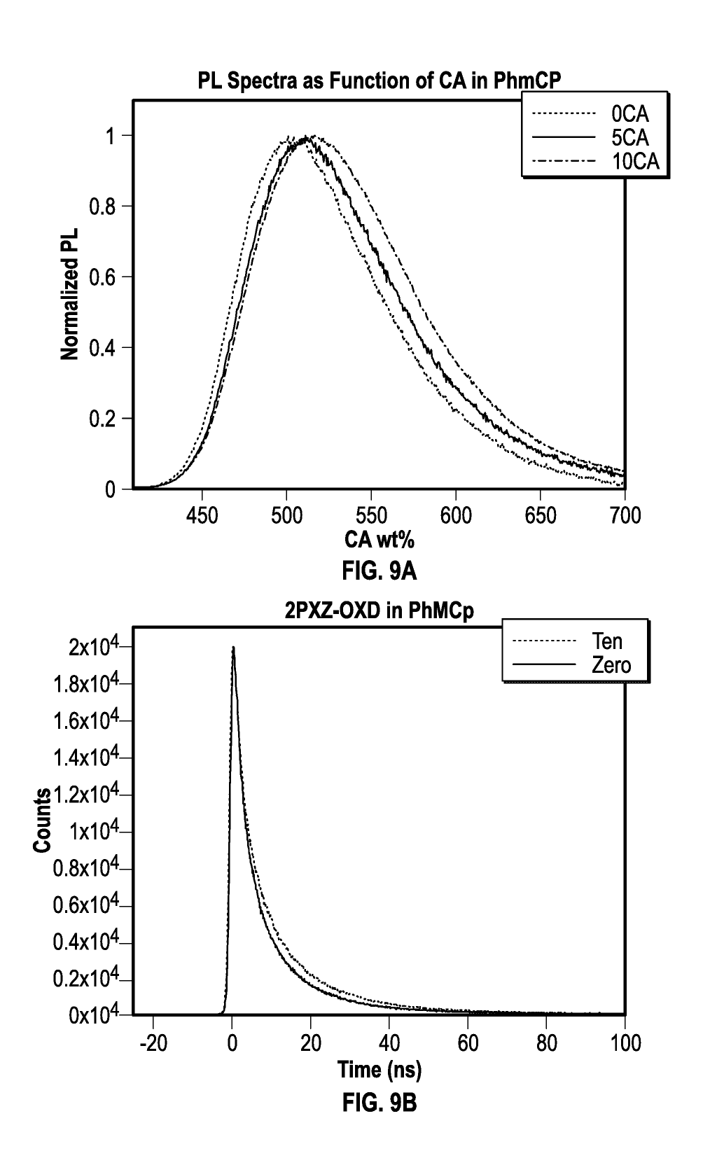

The SSSE on 2PXZ-OXD in another host matrix was evaluated using photoluminescence spectroscopy. The solid state solvation effect was demonstrated using a Ph-mCP host matrix, CA, and 2PXZ-OXD. Photoluminescence spectra were obtained using films are shown in FIG. 9A. The incorporation of 5 wt % and 10 wt % of CA resulted in red-shifted PL spectra based on increasing concentration of CA. As shown in FIG. 9B, the incorporation of 10 wt % of CA resulted in an increase in the average prompt lifetime.

What is claimed is:

1. A composition comprising:
a host material; where the host material can transport a charge;
a fluorescent emitter, wherein the host material and the emitter are different from each other; and
a codopant comprising a small molecule that has a polarity that is different from that of the host material; where the codopant modulates an energy gap of the fluorescent emitter to enhance thermally activated delayed fluorescence of the fluorescent emitter in a solid state.

2. The composition of claim 1, where the fluorescent emitter is a thermally activated delayed fluorescence emitter.

3. The composition of claim 2, where the modulating comprises reducing a singlet-triplet energy gap of the thermally activated delayed fluorescence emitter in a solid state.

4. The composition of claim 3, where a singlet-triplet energy gap of the thermally activated delayed fluorescence emitter is about 0 milli-electron volts to about 300 milli-electron volts and where the codopant provides a solid state solvation effect to the thermally activated delayed fluorescence emitter to facilitate the modulation.

5. The composition of claim 4, where the host material comprises a polymer, a ceramic or a small molecule that is optically transparent.

6. The composition of claim 5, where the polymer is polystyrene, polycarbonate, polymethylmethacrylate, polyetherimides, polyimides, copolymers of ethylene and an α-olefin, copolymers of propylene and an α-olefin, polyester, polyethylene terephthalate, polybutylene terephthalate, or a combination thereof.

7. The composition of claim 1, where the host material is selected from a carbazole compound, a thiophene compound, a sulfonyl compound, a phosphino compound, a phosphoryl compound, a nitrile compound, a fluorene compound, a triazine compound, and a phenoxazine compound.

8. The composition of claim 1, wherein the host material is a phenyl carbazole of the formula: 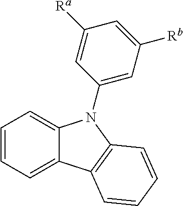
wherein R^{a} and R^{b} are each independently hydrogen, a phosphine oxide, a carbazole, or a C₆ to C₂₄ aryl.

9. The composition of claim 2, wherein the thermally activated delayed fluorescence emitter is selected from a sulfonyl compound, a carbazole compound, a triazole compound, an acridine compound, a triazine compound, a nitrile compound, a phenylpyridine compound, a phenoxazine compound, a fluorene compound, an oxadiazole compound, a xanthene compound, a phenylamino compound, a phenazine compound, an arylboron compound, an organocopper compound, an arylboron-containing compound, an organocopper compound, an organoplatinum compound, an organoiridium compound, an organopalladium compound, or a combination thereof.

10. The composition of claim 2, wherein the thermally activated delayed fluorescence emitter is of the formula:

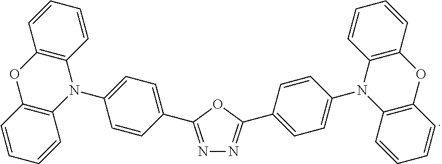 [SMILES: c1ccc2c(c1)Oc1ccccc1N2c1ccc(-c2nnc(-c3ccc(N4c5ccccc5Oc5ccccc54)cc3)o2)cc1]

11. The composition of claim 1, wherein the codopant is selected from a benzoate compound, a hydroxyquinoline compound, an cyclic anhydride compound, a pyrimidinone compound, a dialkylaniline compound, a dione compound, a polycyclic nitrile compound, a quinolinone compound, a zwitterionic compound, an organic salt, or a combination thereof.

12. The composition of claim 1, wherein the codopant is at least one selected from a substituted or unsubstituted C₆-C₃₀ cyclic anhydride and a substituted or unsubstituted C₅-C₂₀ cyclic dione.

13. The composition claim 1, wherein the codopant is at least one selected from camphoric acid anhydride, cyclohexadione, diphenic acid anhydride, methylbenzoate, dimethylaniline, 8-hydroxyquinoline, isatoic anhydride, maleic anhydride, bromomaleic anhydride, phenylmaleic anhydride, phenylsuccinic anhydride, 2-Phenylbutyric acid anhydride, 2-phenylglutaric anhydride, 4-tert-butylphthalic anhydride, 2-(triphenylphosphoranylidene)succinic anhydride, p-toluenesulfonic anhydride, 1-Phenyl-2,3-naphthalenedicarboxylic anhydride, dodecenylsuccinic anhydride, 1,3-dimethyl-3,4,5,6-tetrahydro-2-pyrimidinone, 1,4-dihydroisoquinolin-3(2H)-one, or a combination thereof.

14. An emissive layer manufactured from the composition of claim 1.

15. A device comprising:
an electron transport layer;
a hole transport layer; and
the emission layer of claim 14.

16. A method comprising:
blending together a host material, a fluorescent emitter, and a codopant to form a composition, wherein the host material and the emitter are different from each other; and wherein the codopant comprises a small molecule that has a different polarity from that of the host material; where the codopant modulates an energy gap of the fluorescent emitter to enhance thermally activated delayed fluorescence of the fluorescent emitter in a solid state.

17. The method of claim 16, further comprising extruding the composition or casting the composition.

18. The method of claim 16, further comprising vapor depositing the host material, the fluorescent emitter and the codopant on a substrate.
